(19) United States
(12) Patent Application Publication
(10) Pub. No.: US 2017/0003365 A1
(43) Pub. Date: Jan. 5, 2017

(54) SYSTEM AND METHOD FOR MAGNETIC RESONANCE FINGERPRINTING

(71) Applicant: THE GENERAL HOSPITAL CORPORATION, Boston, MA (US)

(72) Inventors: Matthew S. Rosen, Somerville, MA (US); Mathieu Sarracanie, Somerville, MA (US); Brandon Armstrong, Brighton, MA (US)

(21) Appl. No.: 15/125,670

(22) PCT Filed: Mar. 13, 2015
(86) PCT No.: PCT/US15/20511

§ 371 Date: Sep. 13, 2016

Related U.S. Application Data
(60) Provisional application No. 61/953,377, filed on Mar. 14, 2014.
(60) Provisional application No. 62/030,423, filed on Jul. 29, 2014.

(51) Int. Cl. G01R 33/50; G01R 33/44; G01R 33/48

(52) U.S. Cl. CPC G01R 33/50; G01R 33/4826; G01R 33/4822; G01R 33/445; G01R 33/4804

(57) ABSTRACT

A system and method for generating a report about a subject positioned within a bore of a magnetic resonance imaging (MRI) system includes controlling the MRI system to perform a magnetic resonance fingerprinting (MRF) pulse sequence that at least partially samples k-space using either fractional Cartesian or non-Cartesian sequential sampling pattern to acquire imaging data from the subject. The process also includes estimating quantitative parameters by comparing the acquired imaging data with at least one database comprising a plurality signal templates.

### CROSS-REFERENCE TO RELATED APPLICATIONS

This application is based on, claims priority to, and incorporates herein by reference in its entirety, U.S. Provisional Application Ser. No. 61/953,377, filed Mar. 14, 2014, and entitled, “SYSTEM AND METHOD FOR MAGNETIC RESONANCE FINGERPRINTING” and is based on, claims priority to, and incorporates herein by reference in its entirety, U.S. Provisional Application Ser. No. 62/030,423, filed Jul. 29, 2014, and entitled, “SYSTEM AND METHOD FOR MAGNETIC RESONANCE FINGERPRINTING”

### STATEMENT REGARDING FEDERALLY SPONSORED RESEARCH

This invention was made with government support under W81XWH-11-2-076 awarded by the Department of Defense. The government has certain rights in the invention.

### BACKGROUND

The present disclosure relates to systems and methods for magnetic resonance imaging (MRI) and, more particularly, to systems and methods related to MRI fingerprinting.

When a substance such as human tissue is subjected to a uniform magnetic field (polarizing field B₀), the individual magnetic moments of the excited nuclei in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, M_{z}, may be rotated, or “tipped”, into the x-y plane to produce a net transverse magnetic moment Mₜ. A signal is emitted by the excited nuclei or “spins”, after the excitation signal B₁ is terminated, and this signal may be received and processed to form an image.

When utilizing these “MR” signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

Magnetic resonance fingerprinting (MRF) is an imaging technique that enables quantitative mapping of tissue or other material properties based on random or pseudorandom measurements of the subject or object being imaged. Examples of parameters that can be mapped include longitudinal relaxation time, T₁; transverse relaxation time, T₂; main magnetic field map, B₀; and proton density, ρ. Some basics on MRF are generally described in U.S. Pat. No. 8,723,518, which is herein incorporated by reference in its entirety.

The random or pseudorandom measurements obtained in MRF techniques are achieved by varying the acquisition parameters from one repetition time (TR) period to the next, which creates a time series of images with varying contrast. Examples of acquisition parameters that can be varied include flip angle, radio frequency (RF) pulse phase, TR, echo time (TE), and sampling patterns, such as by modifying one or more readout encoding gradients.

The data acquired with MRF techniques are compared with a dictionary of signal models, or templates, that have been generated for different acquisition parameters from magnetic resonance signal models, such as Bloch equation-based physics simulations. This comparison allows estimation of the desired physical parameters, such as those mentioned above. The parameters for the tissue or other material in a given voxel are estimated to be the values that provide the best signal template matching.

Unfortunately, standard or high-field MRI instruments are large and inflexible systems that cannot be deployed to the field or be made portable. Though many efforts have been made to create what, ostensibly, is a portable MRI system, such systems have very limited capabilities with respect to speed and resolution.

### SUMMARY

The present disclosure overcomes the aforementioned drawbacks by providing for low-field, magnetic resonance or nuclear magnetic resonance imaging that can provide valuable clinical data at low-fields without extensive acquisition times or clinically-damaged images due to low signal-to-noise ratio (SNR) or general contrast. As such, the present disclosure provides a system and method that serves the needs for many clinical settings and is free from many of the system requirements of high-field scanners, such as are common today. More particularly, the systems and method can use high-efficiency steady state free precession techniques (b-SSFP) and undersampling for compressed sensing MRI. The present disclosure allows for MR fingerprinting and, thereby, the simultaneous quantification of multiple properties of a material or tissue in a single acquisition using a low-field MRI system.

In accordance with one aspect of the disclosure, a magnetic resonance imaging (MRI) system is provided that includes a magnet system configured to generate a polarizing magnetic field about at least a region of interest (ROI) of a subject. The MRI system also includes a radio frequency (RF) system configured to apply RF excitation fields to the subject and acquire imaging data therefrom and a computer programmed to control the RF system to perform a magnetic resonance fingerprinting (MRF) pulse sequence that at least partially samples k-space at least one of a fractional Cartesian and/or non-Cartesian sequential sampling pattern to acquire imaging data from the ROI. The computer is further programmed to estimate quantitative parameters by comparing the acquired imaging data with at least one database comprising a plurality signal templates and generate a report indicating the quantitative parameters.

In accordance with another aspect of the disclosure, a method is provided for generating a report about a subject positioned within a bore of a magnetic resonance imaging (MRI) system. The method includes controlling the MRI system to perform a magnetic resonance fingerprinting (MRF) pulse sequence that at least partially samples k-space using at least one of a fractional Cartesian and/or a non-Cartesian, sequential sampling pattern to acquire imaging data from the subject. The method also includes estimating quantitative parameters by comparing the acquired imaging data with at least one database comprising a plurality signal templates.

In accordance with yet another aspect of the disclosure, a method is provided for generating magnetic resonance imaging (MRI) fingerprints (MRF) for a subject. The method includes receiving an indication of a k-space sampling strategy for acquiring MRF data from the subject. The indication includes a selection of one of a Cartesian acquision of k-space or a non-Cartesian acquisition of k-space and one of a full sampling of k-space or an undersampling of k-space. The method also includes controlling an RF system of an MRI system to perform a magnetic resonance fingerprinting (MRF) pulse sequence created using the indication of the k-space sampling strategy to acquire MRF data from the subject. The method further includes estimating quantitative parameters associated with the subject by comparing the MRF data with at least one database comprising a plurality signal templates and generating a report indicating the quantitative parameters.

The foregoing and other advantages of the invention will appear from the following description.

### BRIEF DESCRIPTION OF THE DRAWINGS

FIG. 1 is a block diagram of an MRI system.

FIG. 2 is a block diagram of an RF system of an MRI system.

FIG. 3 is a block diagram of an RF system of an MRI system configured for performing parallel MRI (pMRI) processes

FIG. 4 is a schematic illustration of a low-field MRI (IfMRI) system in accordance with the present disclosure.

FIG. 5 is a schematic illustration of a pulse sequence in accordance with the present disclosure.

FIG. 6A is a schematic image of a phantom used in accordance with the present disclosure.

FIG. 6B is a an M0 image acquired in accordance with the present disclosure.

FIG. 6C is a T1 weighted image acquired in accordance with the present disclosure.

FIG. 6D is a T2 weighted image acquired in accordance with the present disclosure.

FIG. 6E is an off-resonance frequency image acquired in accordance with the present disclosure.

FIG. 7 is a graph showing magnetization trajectory of a single typical voxel over a multi-image fingerprinting sequence in accordance with the present disclosure.

FIG. 8 is a flow chart setting forth an example of steps of a process for creating and using a pulse sequence in accordance with the present disclosure.

### DETAILED DESCRIPTION

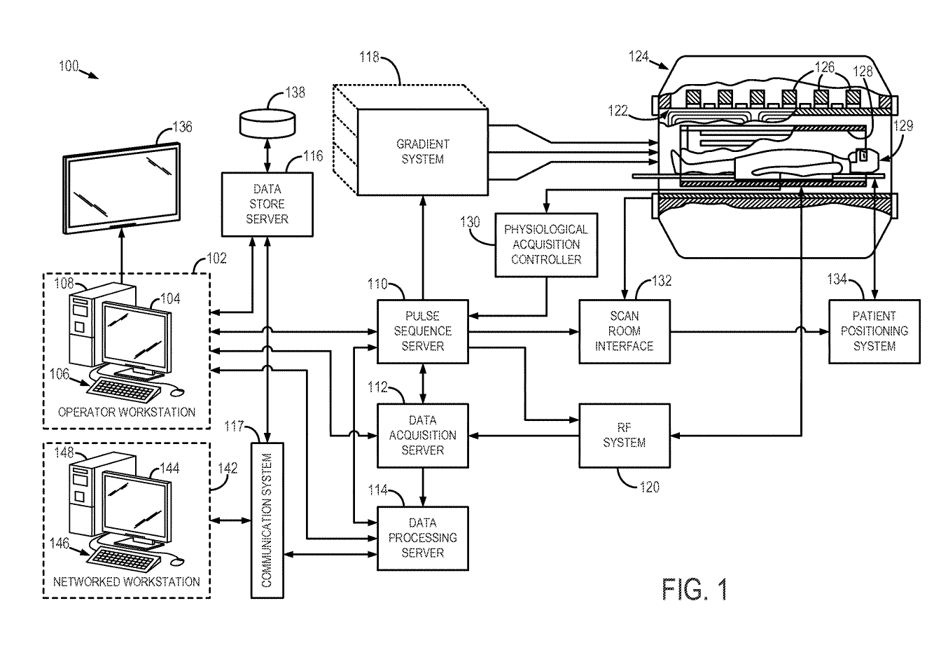

Referring particularly now to FIG. 1, an example of a magnetic resonance imaging (MRI) system 100 is illustrated. The MRI system 100 includes an operator workstation 102, which will typically include a display 104, one or more input devices 106, such as a keyboard and mouse, and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to four servers: a pulse sequence server 110; a data acquisition server 112; a data processing server 114; and a data store server 116. The operator workstation 102 and each server 110, 112, 114, and 116 are connected to communicate with each other. For example, the servers 110, 112, 114, and 116 may be connected via a communication system 117, which may include any suitable network connection, whether wired, wireless, or a combination of both. As an example, the communication system 117 may include both proprietary or dedicated networks, as well as open networks, such as the internet.

The pulse sequence server 110 functions in response to instructions downloaded from the operator workstation 102 to operate a gradient system 118 and a radiofrequency (“RF”) system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding magnetic resonance signals. The gradient coil assembly 122 forms part of a magnet assembly 124 that includes a polarizing magnet 126 and a whole-body RF coil 128 and/or local coil, such as a head coil 129.

RF waveforms are applied by the RF system 120 to the RF coil 128, or a separate local coil, such as the head coil 129, in order to perform the prescribed magnetic resonance pulse sequence. Responsive magnetic resonance signals detected by the RF coil 128, or a separate local coil, such as the head coil 129, are received by the RF system 120, where they are amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays, such as the head coil 129.

The RF system 120 also includes one or more RF receiver channels. Each RF receiver channel includes an RF preamplifier that amplifies the magnetic resonance signal received by the coil 128/129 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

m=\sqrt{I²+Q²} (0);

and the phase of the received magnetic resonance signal may also be determined according to the following relationship:

$$ϕ = {tan}^{- 1} ( \frac{Q}{I} ) . \qquad ( 0 )$$

The pulse sequence server 110 also optionally receives patient data from a physiological acquisition controller 130. By way of example, the physiological acquisition controller 130 may receive signals from a number of different sensors connected to the patient, such as electrocardiograph (ECG) signals from electrodes, or respiratory signals from a respiratory bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than pass the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also be employed to process magnetic resonance signals used to detect the arrival of a contrast agent in a magnetic resonance angiography (MRA) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 114 are conveyed back to the operator workstation 102 where they are stored. Real-time images are stored in a data base memory cache (not shown in FIG. 1), from which they may be output to operator display 112 or a display 136 that is located near the magnet assembly 124 for use by attending physicians. Batch mode images or selected real time images are stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144; one or more input devices 146, such as a keyboard and mouse; and a processor 148. The networked workstation 142 may be located within the same facility as the operator workstation 102, or in a different facility, such as a different healthcare institution or clinic.

The networked workstation 142, whether within the same facility or in a different facility as the operator workstation 102, may gain remote access to the data processing server 114 or data store server 116 via the communication system 117. Accordingly, multiple networked workstations 142 may have access to the data processing server 114 and the data store server 116. In this manner, magnetic resonance data, reconstructed images, or other data may exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

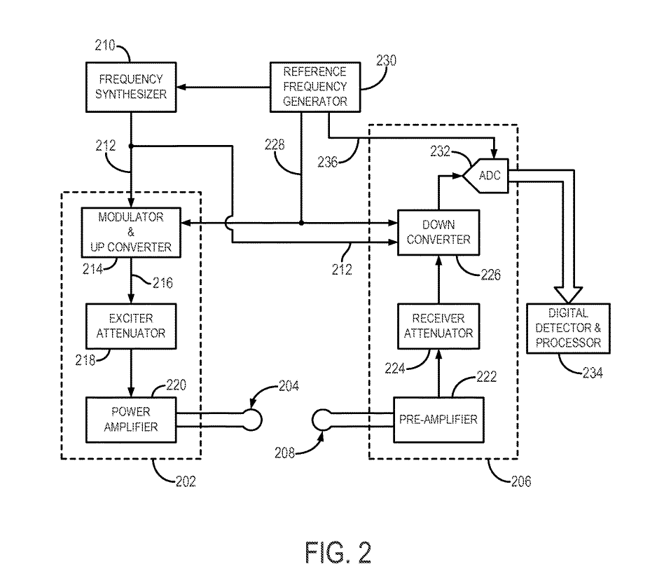

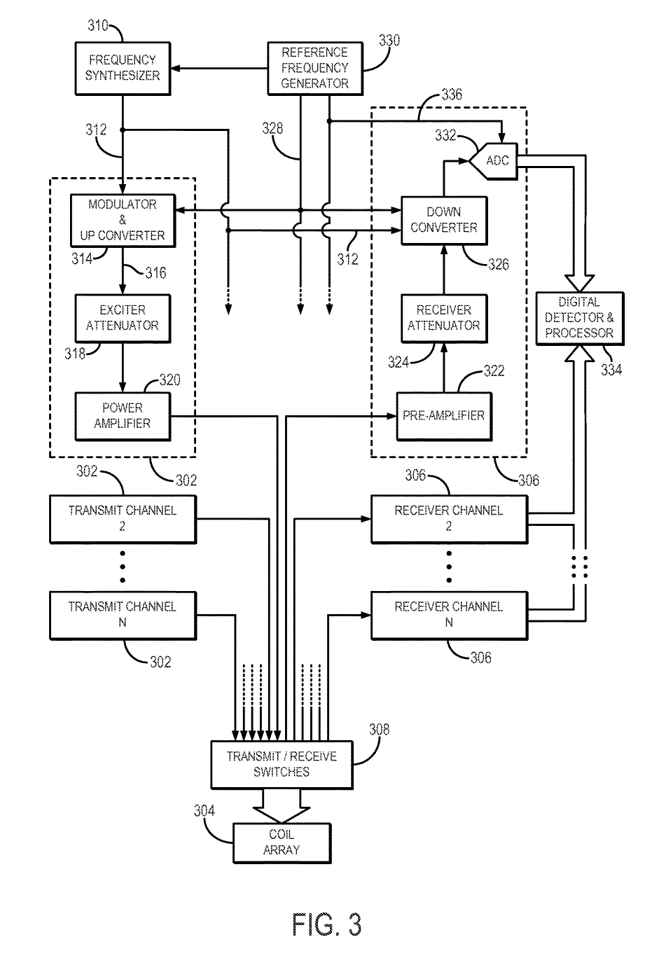

With reference to FIGS. 2 and 3, the RF system 120 of FIG. 1 will be further described. In particular, with reference to FIG. 2, the generalities of the RF system 120 will be described and, with reference to FIG. 3, an example of an RF system 120 adapted for parallel imaging applications will be described.

Referring to FIG. 2, the RF system 120 includes a transmission channel 202 that produces a prescribed RF excitation field. The base, or carrier, frequency of this RF excitation field is produced under control of a frequency synthesizer 210 that receives a set of digital signals from the pulse sequence server 110. These digital signals indicate the frequency and phase of the RF carrier signal produced at an output 212. The RF carrier is applied to a modulator and up converter 214 where its amplitude is modulated in response to a signal, R(t), also received from the pulse sequence server 110. The signal, R(t), defines the envelope of the RF excitation pulse to be produced and is produced by sequentially reading out a series of stored digital values. These stored digital values may be changed to enable any desired RF pulse envelope to be produced.

The magnitude of the RF excitation pulse produced at output 216 is attenuated by an exciter attenuator circuit 218 that receives a digital command from the pulse sequence server 110. The attenuated RF excitation pulses are then applied to a power amplifier 220 that drives the RF transmission coil 204.

The MR signal produced by the subject is picked up by the RF receiver coil 208 and applied through a preamplifier 222 to the input of a receiver attenuator 224. The receiver attenuator 224 further amplifies the signal by an amount determined by a digital attenuation signal received from the pulse sequence server 110. The received signal is at or around the Larmor frequency, and this high frequency signal is down converted in a two step process by a down converter 226. The down converter 226 first mixes the MR signal with the carrier signal on line 212 and then mixes the resulting difference signal with a reference signal on line 228 that is produced by a reference frequency generator 230. The down converted MR signal is applied to the input of an analog-to-digital (“A/D”) converter 232 that samples and digitizes the analog signal. The sampled and digitized signal is then applied to a digital detector and signal processor 234 that produces 16-bit in-phase (I) values and 16-bit quadrature (Q) values corresponding to the received signal. The resulting stream of digitized I and Q values of the received signal are output to the data acquisition server 112. In addition to generating the reference signal on line 228, the reference frequency generator 230 also generates a sampling signal on line 236 that is applied to the A/D converter 232.

Referring to FIG. 3, the RF system 120 may be connected to the whole-body RF coil 128 or, as shown in FIG. 3, a transmission section of the RF system 120 may connect to one or more transmit channels 302 of an RF coil array 304 and a receiver section of the RF system 120 may connect to one or more receiver channels 106 of the RF coil array 304, which may be, for example, a head coil 129, such as illustrated in FIG. 1. The transmit channels 302 and the receiver channels 306 are connected to the RF coil array 304 by way of one or more transmit/receive (T/R) switches 308. In alternative configurations of the RF system 128 in which the receive coils are a separate collection of coils than the transmit coils, T/R switches 308 are not needed and are not used. Instead, in such a configuration the receive array is “detuned” during transmission so that it does not couple to the transmitter. Likewise, during reception, the transmitter is detuned. In this manner, the transmit and receive paths do not mix.

Referring particularly to FIG. 3 and also with reference to FIG. 1, the RF system 120 operates the one or more transmit channels 302 to produce a prescribed RF excitation field. The base, or carrier, frequency of this RF excitation field is produced under control of a frequency synthesizer 310 that receives a set of digital signals from the pulse sequence server 110. These digital signals indicate the frequency and phase of the RF carrier signal produced at an output 312. The RF carrier is applied to a modulator and up converter 314 where its amplitude is modulated in response to a signal, R(t), also received from the pulse sequence server 110. The signal, R(t), defines the envelope of the RF excitation pulse to be produced and is produced by sequentially reading out a series of stored digital values. These stored digital values may be changed to enable any desired RF pulse envelope to be produced.

The magnitude of the RF excitation pulse produced at output 316 may be attenuated by an exciter attenuator circuit 318 that receives a digital command from the pulse sequence server 110. The attenuated RF excitation pulses are then applied to a power amplifier 320 that drives the RF coil array 304.

The MR signal produced by the subject is picked up by the RF coil array 302 and applied to the inputs of the set of receiver channels 306. A preamplifier 322 in each receiver channel 306 amplifies the signal, which is then attenuated by a receiver attenuator 324 by an amount determined by a digital attenuation signal received from the pulse sequence server 110. The received signal is at or around the Larmor frequency, and this high frequency signal is down converted in a two step process by a down converter 326. The down converter 326 first mixes the MR signal with the carrier signal on line 312 and then mixes the resulting difference signal with a reference signal on line 328 that is produced by a reference frequency generator 330. The down converted MR signal is applied to the input of an analog-to-digital (A/D) converter 332 that samples and digitizes the analog signal. As an alternative to down conversion of the high frequency signal, the received analog signal can also be detected directly with an appropriately fast A/D converter and/or with appropriate undersampling. The sampled and digitized signal is then applied to a digital detector and signal processor 334 that produces 16-bit in-phase (I) values and 16-bit quadrature (Q) values corresponding to the received signal. The resulting stream of digitized I and Q values of the received signal are output to the data acquisition server 112. In addition to generating the reference signal on line 328, the reference frequency generator 330 also generates a sampling signal on line 336 that is applied to the A/D converter 332.

Magnetic resonance fingerprinting (MRF) (such as described in Ma D et al. Nature 2013 495:187-193, which is incorporated herein by reference in its entirety) is a technique that can be used for simultaneous quantification of multiple properties of a material or tissue in a single acquisition. In general, MRF techniques utilize a data acquisition scheme that causes signals from different materials or tissues to be spatially and temporally incoherent by continuously varying acquisition parameters throughout the data acquisition process. Examples of acquisition parameters that can be varied include flip angle, radio frequency (RF) pulse phase, repetition time (TR), echo time (TE), and sampling patterns, such as by modifying readout encoding gradients. Preferably, the acquisition parameters are varied in a pseudorandom manner. As a result of the spatial and temporal incoherence imparted by the this acquisition scheme, each material or tissue is associated with a unique signal evolution or “fingerprint,” that is a function of multiple different physical parameters, including longitudinal relaxation time, T₁; transverse relaxation time, T₂; main magnetic field map, B₀; and proton density, ρ.

Quantitative parameter maps can be generated from these acquired signals based on a comparison of the signals to a predefined dictionary of predicted signal evolutions. Each of these dictionaries is associated with different combinations of materials and acquisition parameters. As an example, the comparison of the acquired signals to a dictionary can be performed using any suitable matching or pattern recognition technique. This comparison results in the selection of a signal vector, which may constitute a weighted combination of signal vectors, from the dictionary that best corresponds to the observed signal evolution. The selected signal vector includes values for multiple different quantitative parameters, which can be extracted from the selected signal vector and used to generate the relevant quantitative parameter maps.

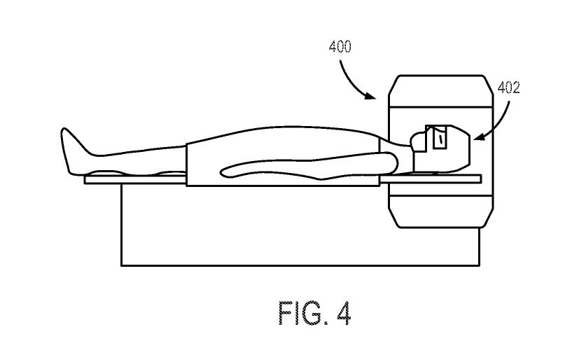

The basic MR systems and principles described above may be used to inform the design of other MR systems that share similar components but operate at very-different parameters. In one example, a low-field magnetic resonance imaging (IfMRI) system utilizes much of the above-described hardware, but has substantially reduced hardware requirements and a smaller hardware footprint. For example, referring to FIG. 4, a system is illustrated that, instead of a 1.5T or greater static magnetic field, utilizes a substantially smaller magnetic field. That is, as a non-limiting example, the system of FIG. 4 may have a static magnetic field of less than 10 mT. As a further a non-limiting example, a 6.5 mT electromagnet-based scanner 400 is illustrated that is capable of imaging objects up to, for example, 15.6 cm in diameter. The system 400 may use a multi-channel array 402 to implement a parallel imaging process, such as a sensitivity encoding (SENSE) imaging procedure.

The system 400 is a relatively transportable and rapidly deployable human imaging system. Current research for low field human imaging is limited and generally uses superconducting quantum interference device (SQUID) sensors. At conventional magnetic field strengths body noise dominates, resulting in strongly correlated noise on each receive coil in the parallel array. At low field, uncorrelated Johnson noise dominates, providing a benefit to parallel imaging and accelerated imaging using, for example, SENSE. However, to perform such parallel imaging techniques, a multi-channel coil is required. Thus, the present disclosure provides a multi-channel coil array 402 that is particularly advantageous.

When extended to IfMRI, MRF creates a rapid dynamic series of low signal to noise ratio (SNR) images where the magnitude of each voxel of each image changes at every time step. The TR and flip angle of each image in the time series can be varied pseudo-randomly. No steady state is reached, and image voxels with different relaxation times evolve differently, thereby generating unique magnetization trajectories. The time evolution of each voxel can be determined using the Bloch equations with the TR and flip angle patterns used for the imaging sequence over a wide range of tissue parameters, and a database (dictionary) of trajectories specific to the IfMRI system can be used. With such in hand, the measured voxel trajectory can be compared to the dictionary and the best match chosen, providing the T1, T2, and off-resonance frequency value of that voxel.

The present disclosure recognizes that a lack of SNR at low magnetic field strengths causes the traditional MRF paradigm to fail. Thus, the present disclosure provides a new pulse sequence that overcomes these limitations. For example, as will be described, the new pulse sequence can provide lower undersampling rates and increased flip angle range over traditional techniques and, as will be described, such can be leveraged to make MRF practical with IfMRI systems.

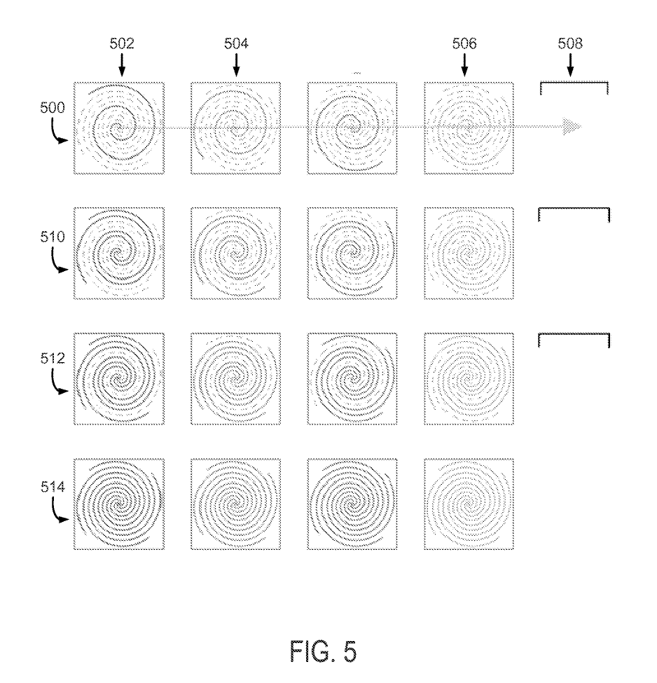

For example, referring to FIG. 5, one example of an MRF pulse sequence in accordance with the present disclosure is illustrated. As illustrated, a spiral k-space sampling trajectory can be used to fully or partially sample k-space in a sequential fashion. The sequence starts by acquiring a first set of spirals 500 from “k-space 1” 502 (using alpha 1 and TR 1), to “k-space 2” 504 (using alpha 2 and TR2), through “k-space n” 506 (using alpha n and TR n). A pause 508 may be used that is a duration selected to allows the spins in the sample to return to equilibrium before going to the next step.

After the pause, a second set of spirals 510 is acquired from k-space 1 502 through k-space n 206 followed by a pause 508. The sampling of each k-space (1 through n) uses its own TR and flip angle alpha values and, as necessary, its own pause duration. As will be described, alpha values can be selected as part of a process for building a desired MR fingerprinting pulse sequence, for example, that may acquire less than one image per TR. After each k-space sampling 500, 510, 512, 514, the pause may be applied. This way, the acquisitions can be started in the same conditions.

This process continues with a third set of spirals 512 and a forth set of spirals 514 and so on until each k-space (with its own TR and flip angle alpha) is fully or partially sampled as designed by the user. The same approach can be used for Cartesian acquisition of k-space, with or without under-sampling. In a Cartesian implementation, lines in k-space are acquired instead of spirals.

In accordance with the present disclosure, an MRF pulse sequence can sample k-space fully or partially in a sequential fashion. Cartesian acquisition schemes can be added to non-Cartesian acquisition strategies for MRF to thereby enable robust image reconstruction. MRF can be performed with very short TR and be used in combination with respiratory or cardiac gating strategies. Fractional Cartesian and non-Cartesian MRF can be implemented at magnetic fields ranging from very low (<10 mT) to very high (>10T) magnitudes.

As such, a system and method is provided to implement MRF so that a user defined fraction (including the whole) of k-space may be acquired in a sequential fashion, in two or three dimensions. To this end, fractional Cartesian and non-Cartesian MRF can be used to characterize biological and non-biological systems including but not limited to quantitative maps of their relaxation properties (T1,T2), off-resonance, temperature, and proton density. For example, fractional Cartesian and non-Cartesian MRF can be used in the biochemical and chemical industries for the characterization of new molecules and compounds. It can be used in the security industry, typically in area with dense population traffic, to identify potentially dangerous substances.

In the fields of biology and medicine, fractional Cartesian and non-Cartesian MRF can be used to characterize and/or monitor changes in biological systems, including internal organs or structures, tumors in human and animals, in a quantitative and reproducible way. When combined with gating strategies, it can also be used for such characterization in dynamic systems including systems with flowing liquids and systems where structure changes over time.

One particular example of such a pulse sequence includes 200 time points and a 50 percent undersampling and uses a slice-selective, 20 spirals pulse sequence. In this example, after an inversion pulse, the flip angle ranges between 30 and 107 degrees and the TR varies between 46.1 ms and 52.7 ms. A dictionary was made of 2,751,975 signal time courses, each with 200 time points. MR total acquisition time was 13 min. The sequence was set with voxel size 3×3×10 mm3, FOV: 144×144×10 mm3, number of average (NA): 6. This was done with the above-described IfMRI scanner.

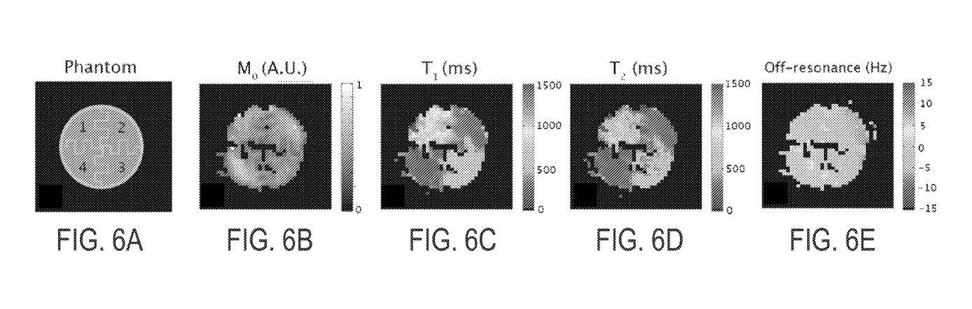

That is, slice-selective MRF results were obtained using 6.5 mT IfMRI system. A four-compartment, liquid-filled, structured phantom having varied relaxation properties was used. Each compartment had T1 and T2 measured in separate reference experiments (Inversion recovery & T2 CPMG respectively). 1: T1=1046 ms, T2=700 ms, 2: T1=425 ms, T2=418 ms, 3: T1=600 ms, T2=591 ms, 4: T1=340 ms, T2=286 ms. Referring to FIG. 6, FIG. 6A, a schematic image of the phantom is provided. FIGS. 6B through 6E show M0, T1, T2, and off-resonance frequency, weighted images respectively.

Thus, FIGS. 6A through 6E represent an example of a set images of fingerprinting images. Each image in the reconstructed fingerprinting set revealed different information. The spin density (M0) map of FIG. 6B is equivalent to traditional b-SSFP, and no visible difference between compartments is seen. However, FIGS. 6C through 6D reveals that compartments 1-4 have very different T1 and T2 relaxation properties. The MRF images show good agreement with the reference measurements. Additionally, a map of the magnetic field homogeneity of the LFI scanner was also generated during the MRF sequence and is shown in FIG. 6E.

Thus, MR fingerprinting has been adapted for low magnetic field strengths and IfMRI. In particular, the present disclosure provides a system and method by which results in simultaneous measurement of, as a non-limiting example, 4 quantitative parameters. Thus, the present systems and methods can provide multiple different image contrasts (in this non-limiting example, 4 contrasts provided by proton density, T1, T2 and off-resonance) in a single acquisition, which in this non-limiting example took less than 15 minutes. This technique is of particular relevance at low magnetic field where SNR and contrast are tied to long acquisition times. However, it can likewise be used at higher field strengths. The combination of MRF with IfMRI scanners has great potential to revolutionize future transportable MRI systems.

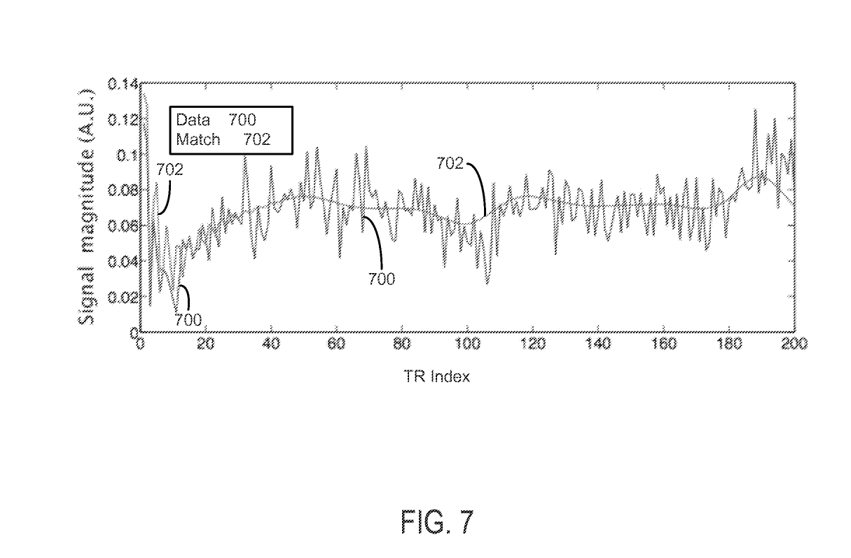

FIG. 7 is a graph showing the magnetization trajectory of a single typical voxel over the 200 image fingerprinting sequence is shown, showing the underlying data 700 data and the best match from dictionary 702. All the parameters of the voxel (M0, T1, T2, and off-resonance frequency) were determined once the trajectory match was determined.

In addition to the utility of providing systems and methods that allow MRF to be extended to IfMRI, the present disclosure provides substantial advantages by providing systems and methods for fractional Cartesian and non-Cartesian MRF. For example, the present disclosure provides a system and method to implement MRF so that a user defined fraction (including the whole) of k-space may be acquired in a sequential fashion, in two or three dimensions. To this end, Fractional Cartesian and non-Cartesian MRF can be used to characterize biological and non-biological systems including but not limited to quantitative maps of their relaxation properties (T1,T2), off-resonance, temperature, and proton density.

Fractional Cartesian and non-Cartesian MRF can be used in the biochemical and chemical industries for the characterization of new molecules and compounds. It can be used in the security industry, typically in area with dense population traffic, to identify potentially dangerous substances.

In the fields of biology and medicine, fractional Cartesian and non-Cartesian MRF can be used to characterize and/or monitor changes in biological systems, including internal organs or structures, tumors in human and animals, in a quantitative and reproducible way. When combined with gating strategies, it can also be used for such characterization in dynamic systems including systems with flowing liquids and systems where structure changes over time.

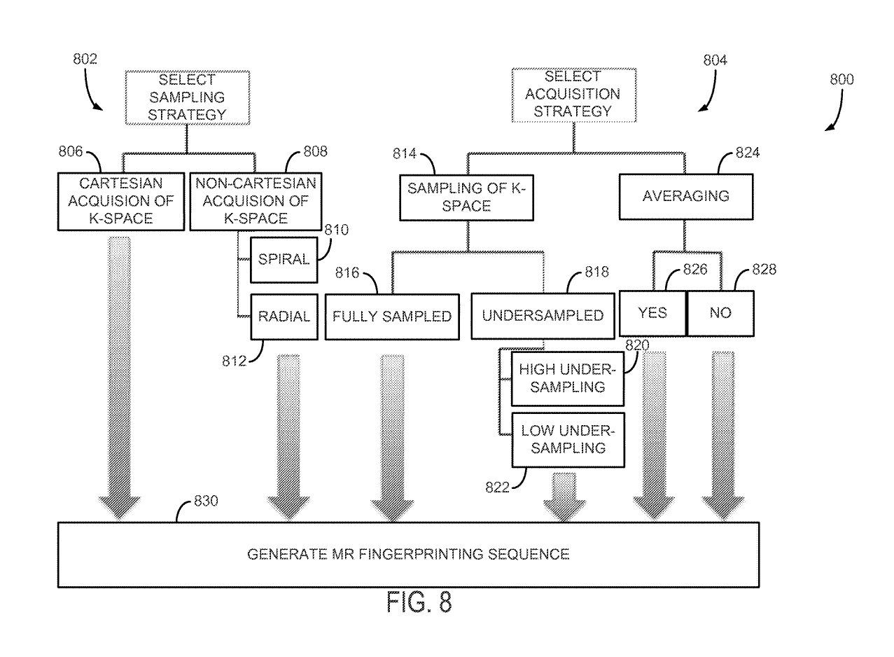

Referring to FIG. 8, a process 800 for generating an MR fingerprinting pulse sequence in accordance with the present disclosure can be conceptually broken into two sub-processes 802, 804. The first sub-process 802 is directed to selecting a sampling strategy and allows a user to select between a Cartesian acquision of k-space 806 and a non-Cartesian acquisition of k-space 808. If a non-Cartesian acquisition 808 is selected, a sampling pattern, such as a spiral pattern 810 or a radial patter 812 may be selected.

The second sub-process 804 is directed to selecting an acquisition sampling, which may include selection of a sampling of k-space 814 that may be a full sampling 816 or an under sampling 818. If undersampling, the understampling can be at a high rate 820 or low rate 822. Also, averaging may be considered 814 and selected 826 or rejected 828.

Thus, as opposed to traditional MR fingerprinting techniques, fractional acquisition of k-space applied to MR fingerprinting allows to broaden its use to Cartesian and non-Cartesian strategies, as well as full or partial sampling of k-space and also averaging. The flexibility provided is of particular interest when signal to noise ratio (SNR) in the acquired image is low. Cartesian acquisition strategies also add a tremendous improvement for robustness in the case of image reconstruction. That is, traditional MR fingerprinting implementations have relied on, at most, spiral sampling 810 with high undersampling 820 and require one image to be acquired per TR. This has necessarily precluded the use of Cartesian sampling strategies because one cannot acquire one image per TR in a Cartesian acquisition. However, the present disclosure allow the standard paradigm of one image per TR to be broken by, for example, allowing each k-space sampling to use its own TR and flip angle alpha, as described above with respect to FIG. 5.

Thus, the present disclosure provides a substantial framework for a user to build a pulse sequence having any of a variety of characteristics and capabilities for MR fingerprinting applications. That is, the decision process illustrated with respect to FIG. 8 can be embodied as a software tool that allow the user to make choices consistent with FIG. 8 and, based thereon, builds or generates an MR fingerprinting pulse sequence 830.

As used herein, “and/or” indicates the combination of the disjunctive “or” and the conjunctive “and” in a selective manner. Thus, when two or more items are identified in a list separated by “and/or,” one may select only one item from the list or may select one item and any number of additional items from the list, or additional items not indicated in the list.

The present invention has been described in terms of one or more embodiments, and it should be appreciated that many equivalents, alternatives, variations, and modifications, aside from those expressly stated, are possible and within the scope of the invention.

1. A magnetic resonance imaging (MRI) system comprising:
a magnet system configured to generate a polarizing magnetic field about at least a region of interest (ROI) of a subject;
a radio frequency (RF) system configured to apply RF excitation fields to the subject and acquire imaging data therefrom; and
a computer programmed to:
control the RF system to perform a magnetic resonance fingerprinting (MRF) pulse sequence that at least partially samples k-space using a fractional Cartesian or non-Cartesian sampling pattern to acquire imaging data from the ROI;
estimate quantitative parameters associated with the subject by comparing the acquired imaging data with at least one database comprising a plurality signal templates; and
generate a report indicating the quantitative parameters.

2. The system of claim 1 wherein the quantitative parameters included in the report include at least one of T1 relaxation properties of the subject, T2 relaxation properties of the subject, off-resonance properties of the subject, temperature of the subject, and/or proton density of the subject.

3. The system of claim 1 wherein the magnet system has a magnetic field strength of less than 10 mT.

4. The system of claim 1 wherein the MRF pulse sequence includes a repetition time (TR) of less than 60 ms.

5. The system of claim 1 further comprising at least one physiological monitoring system configured to communicate at least one of a reparatory gating signal and a cardiac gating signal to the computer and wherein the computer is further programmed to control the RF system to perform the MRF pulse sequence with at least one of a respiratory gating process and/or a cardiac gating process.

6. The system of claim 1 wherein the magnet system has a magnetic field strength of less than 6.5 mT.

7. The system of claim 1 wherein the computer is further programmed to receive a user-defined fraction of k-space to be acquired using the MRF pulse sequence.

8. The system of claim 7 wherein the computer is further programmed to develop a sequential sampling pattern for sampling k-space using the user-defined fraction.

9. The system of claim 7 wherein the computer is further programmed to sample k-space in one of two or three dimensions.

10. The system of claim 1 wherein the report includes a quantitative map of at least one of a T1 relaxation property, a T2 relaxation property, off-resonance, temperature, and proton density.

11. A method for generating magnetic resonance imaging (MRI) fingerprints (MRF) for a subject, the method comprising:
receiving an indication of a k-space sampling strategy for acquiring MRF data from the subject, including:
a selection of one of a Cartesian acquision of k-space or a non-Cartesian acquisition of k-space;
one of a full sampling of k-space or an undersampling of k-space;
controlling an RF system of an MRI system to perform a magnetic resonance fingerprinting (MRF) pulse sequence created using the indication of the k-space sampling strategy to acquire MRF data from the subject;
estimating quantitative parameters associated with the subject by comparing the MRF data with at least one database comprising a plurality signal templates; and
generating a report indicating the quantitative parameters.

12. The method of claim 11 wherein the k-space sampling pattern includes one of a spiral or a radial pattern.

13. The method of claim 11 wherein the selection of an undresampling of k-space further includes a selection of a high rate or a low rate of undersampling.

14. The method of claim 11 wherein the quantitative parameters included in the report include at least one of T1 relaxation properties of the subject, T2 relaxation properties of the subject, off-resonance properties of the subject, temperature of the subject, and/or proton density of the subject.

15. The method of claim 11 wherein the MRI system has a static magnetic field of less than 10 mT.

16. The method of claim 11 wherein the MRF pulse sequence includes a repetition time (TR) of less than 60 ms.

17. The method of claim 11 further comprising performing a physiological monitoring of the subject to generate at least one of a reparatory gating signal and a cardiac gating signal and further controlling the RF system to perform the MRF pulse sequence with at least one of a respiratory gating process or a cardiac gating process.

18. The method of claim 11 wherein the MRI system has a static magnetic field of less than 6.5 mT.

19. The method of claim 11 wherein the k-space sampling strategy includes sampling k-space in one of two or three dimensions.

20. The method of claim 11 wherein the report includes a quantitative map of at least one of a T1 relaxation property, a T2 relaxation property, off-resonance, temperature, and proton density
